(19) United States
(12) Patent Application Publication
(10) Pub. No.: US 2024/0396525 A1
(43) Pub. Date: Nov. 28, 2024

(54) ACOUSTIC WAVE DEVICE

(71) Applicant: Murata Manufacturing Co., Ltd., Nagaokakyo-shi (JP)

(72) Inventor: Ryo NAKAGAWA, Nagaokakyo-shi (JP)

(21) Appl. No.: 18/600,880

(22) Filed: Mar. 11, 2024

(30) Foreign Application Priority Data
May 24, 2023 (JP) 2023-085143

(51) Int. Cl. H03H 9/25; H03H 9/02; H03H 9/145

(52) U.S. Cl. CPC H03H 9/25; H03H 9/02637; H03H 9/02866; H03H 9/145

(57) ABSTRACT

An acoustic wave device includes a piezoelectric substrate including a piezoelectric layer, and an IDT electrode on the piezoelectric layer and includes first and second electrode fingers interdigitated with each other and coupled to mutually different potentials. A portion of the piezoelectric layer including the IDT electrode includes an intersection region. When a direction in which the first and second electrode fingers extend is an electrode finger extending direction, a direction orthogonal to the electrode finger extending direction is an electrode finger orthogonal direction, and the IDT electrode is viewed in the electrode finger orthogonal direction, a region where the first and second electrode fingers adjacent to each other overlap each other is the intersection region, the piezoelectric layer includes first and second regions with polarization directions different from each other, and the first region and the second region are positioned at least in the intersection region.

### CROSS REFERENCE TO RELATED APPLICATIONS

This application claims the benefit of priority to Japanese Patent Application No. 2023-085143 filed on May 24, 2023. The entire contents of this application are hereby incorporated herein by reference.

### BACKGROUND OF THE INVENTION

### 1. Field of the Invention

The present invention relates to an acoustic wave device.

### 2. Description of the Related Art

In the related art, acoustic wave devices are widely used as filters of mobile phones and the like. International Publication No. WO 2012/086639 discloses an example of an acoustic wave device. In the acoustic wave device, the support substrate, the high acoustic velocity film, the low acoustic velocity film, and the piezoelectric film are laminated in this order. An interdigital transducer (IDT) electrode is provided on the piezoelectric film. International Publication No. WO 2012/086639 discloses a mode having a P wave as a main component, a mode having a shear horizontal (SH) wave as a main component, and a mode having a shear vertical (SV) wave as a main component, as a main mode that propagates through the piezoelectric film.

### SUMMARY OF THE INVENTION

In the acoustic wave device of the related art as described in International Publication No. WO 2012/086639, it is difficult to preferably excite an acoustic wave having a wavelength longer than the wavelength defined by the electrode finger pitch of the IDT electrode. When such a long wavelength wave is used for the operation of the acoustic wave device, the fundamental wave becomes an unnecessary wave. Therefore, it is necessary to suppress the fundamental wave.

Example embodiments of the present invention provide acoustic wave devices that each excite an acoustic wave having a wavelength approximately twice a wavelength defined by an electrode finger pitch and suppress a fundamental wave.

According to a broad aspect of the present invention, an acoustic wave device includes a piezoelectric substrate including a piezoelectric layer, and an IDT electrode provided on the piezoelectric layer and including a plurality of first electrode fingers and a plurality of second electrode fingers that are interdigitated with each other and coupled to mutually different potentials, in which a portion of the piezoelectric layer where the IDT electrode is provided includes an intersection region, and when a direction in which the plurality of first electrode fingers and the plurality of second electrode fingers extend is defined as an electrode finger extending direction, a direction orthogonal to the electrode finger extending direction is defined as an electrode finger orthogonal direction, and the IDT electrode is viewed in the electrode finger orthogonal direction, a region where the first electrode finger and the second electrode finger, which are adjacent to each other, overlap each other is the intersection region, the piezoelectric layer includes a first region and a second region having a polarization direction different from that of the first region, and the first region and the second region are positioned at least in the intersection region, the intersection region includes a polarization change region where the first region and the second region are alternately arranged in the electrode finger orthogonal direction, in plan view, each first region and each second region positioned in the polarization change region overlap at least a portion of at least one of the first electrode finger and the second electrode finger, when the piezoelectric layer is divided into a plurality of sections in the electrode finger orthogonal direction, each of the plurality of sections is defined as an area extending from a portion where the first electrode finger or the second electrode finger is provided to a portion where the first electrode finger or the second electrode finger is not provided, and only one electrode finger is provided in each of the sections among the plurality of first electrode fingers and the plurality of second electrode fingers, the plurality of sections include first to eighth sections arranged in order in the electrode finger orthogonal direction, a boundary between the first section and the second section is positioned at a portion where the first electrode finger is provided, and the first region is positioned in the first section, the second region is positioned in the second section, the first region is positioned in the third section, the second region is positioned in the fourth section, the second region is positioned in the fifth section, the first region is positioned in the sixth section, the second region is positioned in the seventh section, and the first region is positioned in the eighth section.

According to another broad aspect of an example embodiment of the present invention, an acoustic wave device includes a piezoelectric substrate including a piezoelectric layer, and an IDT electrode provided on the piezoelectric layer and including a plurality of first electrode fingers and a plurality of second electrode fingers that are interdigitated with each other and coupled to mutually different potentials, in which a portion of the piezoelectric layer where the IDT electrode is provided includes an intersection region, and when a direction in which the plurality of first electrode fingers and the plurality of second electrode fingers extend is defined as an electrode finger extending direction, a direction orthogonal to the electrode finger extending direction is defined as an electrode finger orthogonal direction, and the IDT electrode is viewed in the electrode finger orthogonal direction, a region where the first electrode finger and the second electrode finger, which are adjacent to each other, overlap each other is the intersection region, the piezoelectric layer includes a first region and a second region having a polarization direction different from that of the first region, and the first region and the second region are positioned at least in the intersection region, the intersection region includes a polarization change region where the first region and the second region are alternately arranged in the electrode finger orthogonal direction, in plan view, each first region and each second region positioned in the polarization change region overlap at least a portion of at least one of the first electrode finger and the second electrode finger, when the piezoelectric layer is divided into a plurality of sections in the electrode finger orthogonal direction, each of the plurality of sections is defined as an area extending from a portion where the first electrode finger or the second electrode finger is provided to a portion where the first electrode finger or the second electrode finger is not provided, and only one electrode finger is provided in each of the sections among the plurality of first electrode fingers and the plurality of second electrode fingers, the plurality of sections include first to eighth sections arranged in order in the electrode finger orthogonal direction, and the first region is positioned in the first section, the first region is positioned in the second section, the first region is positioned in the third section, the second region is positioned in the fourth section, the second region is positioned in the fifth section, the second region is positioned in the sixth section, the second region is positioned in the seventh section, and the first region is positioned in the eighth section.

According to example embodiments of the present invention, it is possible to provide acoustic wave devices that each excite an acoustic wave having a wavelength approximately twice a wavelength defined by an electrode finger pitch and suppress a fundamental wave.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view illustrating a portion of an acoustic wave device according to a first example embodiment of the present invention.

FIG. 2 is a schematic plan view of the acoustic wave device according to the first example embodiment of the present invention.

FIG. 3 is a schematic plan view of a piezoelectric layer, illustrating a disposition of a first region and a second region according to the first example embodiment of the present invention.

FIG. 4 is a diagram illustrating admittance frequency characteristics in a first example embodiment and a first comparative example of the present invention.

FIG. 5 is a schematic elevational cross-sectional view illustrating a vicinity of two pairs of electrode fingers according to the first comparative example, and is a view for describing that a fundamental wave is excited in the first comparative example.

FIG. 6 is a schematic elevational cross-sectional view illustrating a vicinity of two pairs of electrode fingers according to a second comparative example, and is a view for describing that a fundamental wave is excited in the second comparative example.

FIG. 7 is a schematic elevational cross-sectional view illustrating a relationship between an effective distortion and a charge, in the second comparative example.

FIG. 8 is a schematic elevational cross-sectional view illustrating a vicinity of two pairs of electrode fingers of the acoustic wave device according to the first example embodiment of the present invention, and is a view for describing that a fundamental wave is difficult to be excited in the first example embodiment of the present invention.

FIG. 9 is a schematic elevational cross-sectional view illustrating a vicinity of two pairs of electrode fingers of the acoustic wave device according to the first example embodiment of the present invention, and is a view for describing that a 1/2 harmonic wave is excited in the first example embodiment of the present invention.

FIG. 10 is a schematic elevational cross-sectional view illustrating a vicinity of two pairs of electrode fingers of an acoustic wave device according to a first modification example of the first example embodiment of the present invention.

FIG. 11 is a schematic elevational cross-sectional view illustrating a vicinity of two pairs of electrode fingers of an acoustic wave device according to a second modification example of the first example embodiment of the present invention.

FIG. 12 is a schematic elevational cross-sectional view illustrating a vicinity of two pairs of electrode fingers of an acoustic wave device according to a second example embodiment of the present invention.

FIG. 13 is a diagram illustrating admittance frequency characteristics in the second example embodiment and a first comparative example of the present invention.

FIG. 14 is a schematic elevational cross-sectional view illustrating a vicinity of two pairs of electrode fingers of an acoustic wave device according to the second example embodiment of the present invention, and is a view for describing that a 1/2 harmonic wave is excited in the second example embodiment of the present invention.

FIG. 15 is a schematic elevational cross-sectional view illustrating a vicinity of two pairs of electrode fingers of an acoustic wave device according to a modification example of the second example embodiment of the present invention.

FIG. 16 is a schematic elevational cross-sectional view illustrating a vicinity of two pairs of electrode fingers of an acoustic wave device according to a third example embodiment of the present invention.

FIG. 17 is a schematic elevational cross-sectional view illustrating a vicinity of two pairs of electrode fingers of an acoustic wave device according to a fourth example embodiment of the present invention.

FIG. 18 is a schematic elevational cross-sectional view illustrating a vicinity of two pairs of electrode fingers of an acoustic wave device according to a fifth example embodiment of the present invention.

FIG. 19 is a schematic elevational cross-sectional view illustrating a vicinity of two pairs of electrode fingers of an acoustic wave device according to a sixth example embodiment of the present invention.

FIG. 20 is a schematic elevational cross-sectional view illustrating a vicinity of two pairs of electrode fingers of an acoustic wave device according to a first modification example of the sixth example embodiment of the present invention.

FIG. 21 is a schematic elevational cross-sectional view illustrating a vicinity of two pairs of electrode fingers of an acoustic wave device according to a second modification example of the sixth example embodiment of the present invention.

FIG. 22 is a schematic elevational cross-sectional view illustrating a vicinity of two pairs of electrode fingers of an acoustic wave device according to a third modification example of the sixth example embodiment of the present invention.

FIG. 23 is a schematic elevational cross-sectional view illustrating a vicinity of two pairs of electrode fingers of an acoustic wave device according to a fourth modification example of the sixth example embodiment of the present invention.

### DETAILED DESCRIPTION OF THE EXAMPLE EMBODIMENTS

Hereinafter, the present invention will be elucidated by describing specific example embodiments of the present invention with reference to the accompanying drawings.

It should be pointed out that each example embodiment described in the present specification is an example, and partial replacement or combination of configurations is possible between different example embodiments.

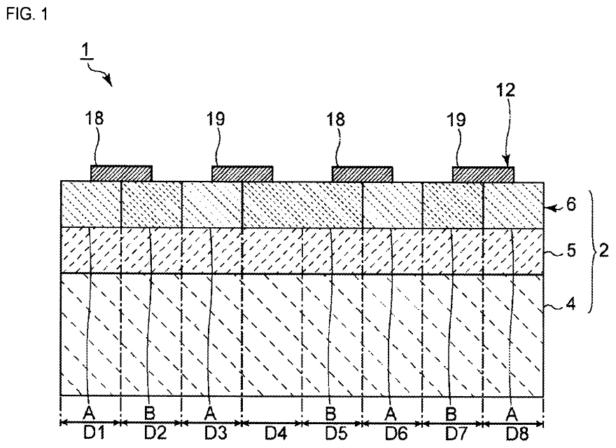

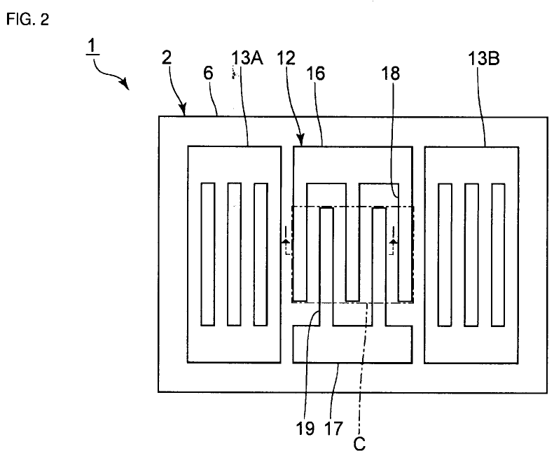

FIG. 1 is a schematic elevational cross-sectional view illustrating a portion of an acoustic wave device according to a first example embodiment of the present invention. FIG. 2 is a schematic plan view of the acoustic wave device according to the first example embodiment. FIG. 1 is a schematic cross-sectional view taken along the line I-I in FIG. 2.

As illustrated in FIG. 1, an acoustic wave device 1 has a piezoelectric substrate 2. The piezoelectric substrate 2 is a substrate having piezoelectricity. The piezoelectric substrate 2 includes a piezoelectric layer 6 made of a piezoelectric material. More specifically, in the present example embodiment, the piezoelectric substrate 2 includes a high acoustic velocity support substrate 4 as a high acoustic velocity layer, a silicon oxide film 5 as a low acoustic velocity film, and the piezoelectric layer 6. The silicon oxide film 5 is provided on the high acoustic velocity support substrate 4. The piezoelectric layer 6 is provided on the silicon oxide film 5. The laminated configuration of the piezoelectric substrate 2 is not limited to the above. The piezoelectric substrate 2 may include at least the piezoelectric layer 6.

As the material of the piezoelectric layer 6, lithium niobate is used. More specifically, as the material of the piezoelectric layer 6, a rotated Y-cut LiNbO₃ is used. However, the material of the piezoelectric layer 6 is not limited to the above. For example, as the material of the piezoelectric layer 6, lithium tantalate such as LiTaO₃ may be used.

An IDT electrode 12 is provided on the piezoelectric layer 6. An acoustic wave is excited by applying an AC voltage to the IDT electrode 12. The acoustic wave device 1 is configured to be able to use a 1/2 harmonic wave. In the present specification, the 1/2 harmonic wave means an acoustic wave having a frequency that is approximately 1/2 times the frequency of the fundamental wave. The wavelength of the 1/2 harmonic wave is approximately twice the wavelength of the fundamental wave. When the 1/2 harmonic wave is used for the operation of the acoustic wave device 1, the fundamental wave becomes an unnecessary wave.

The high acoustic velocity layer, which is the high acoustic velocity support substrate 4, is a relatively high acoustic velocity layer. More specifically, the acoustic velocity of the bulk wave propagating through the high acoustic velocity layer is higher than the acoustic velocity of the acoustic wave propagating through the piezoelectric layer 6. The high acoustic velocity support substrate 4 as a high acoustic velocity layer in the present example embodiment is a silicon substrate. However, the material of the high acoustic velocity layer is not limited to silicon. In addition, the high acoustic velocity layer may be a high acoustic velocity film. In this case, the piezoelectric substrate 2 may have, for example, a support substrate. A high acoustic velocity film may be provided on the support substrate.

The low acoustic velocity film is a film having a relatively low acoustic velocity. More specifically, the acoustic velocity of the bulk wave propagating through the low acoustic velocity film is lower than the acoustic velocity of the bulk wave propagating through the piezoelectric layer 6. The low acoustic velocity film in the present example embodiment is the silicon oxide film 5. However, the material of the low acoustic velocity film is not limited to silicon oxide.

As illustrated in FIG. 2, the IDT electrode 12 includes a pair of busbars and a plurality of electrode fingers. The pair of busbars are specifically a first busbar 16 and a second busbar 17. The first busbar 16 and the second busbar 17 face each other. The plurality of electrode fingers are specifically a plurality of first electrode fingers 18 and a plurality of second electrode fingers 19. One ends of the plurality of first electrode fingers 18 are respectively coupled to the first busbar 16. One ends of the plurality of second electrode fingers 19 are respectively coupled to the second busbar 17. The plurality of first electrode fingers 18 and the plurality of second electrode fingers 19 are interdigitated with each other.

The first electrode finger 18 and the second electrode finger 19 are coupled to potentials different from each other. For example, one of the first electrode finger 18 and the second electrode finger 19 may be coupled to the signal potential, and the other one may be coupled to the ground potential. Alternatively, one of the first electrode finger 18 and the second electrode finger 19 may be coupled to the input potential of the signal potential, and the other one may be coupled to the output potential of the signal potential.

A pair of reflectors 13A and 13B are provided on the piezoelectric layer 6. More specifically, the reflector 13A and the reflector 13B are provided to face each other with the IDT electrode 12 interposed therebetween in the acoustic wave propagation direction. The acoustic wave device 1 is a surface acoustic wave resonator.

In the present example embodiment, the IDT electrode 12 and each reflector include a single layer metal film. Specifically, Al is used as a material of the IDT electrode 12 and each reflector. However, the materials of the IDT electrode 12 and each reflector are not limited to the above. Alternatively, the IDT electrode 12 and each reflector may be made of a laminated metal film.

Hereinafter, a direction in which the plurality of first electrode fingers 18 and the plurality of second electrode fingers 19 extend is defined as an electrode finger extending direction, and a direction orthogonal to the electrode finger extending direction is defined as an electrode finger orthogonal direction. The electrode finger orthogonal direction and the acoustic wave propagation direction are parallel to each other. When the IDT electrode 12 is viewed in the electrode finger orthogonal direction, a region where the first electrode finger 18 and the second electrode finger 19, which are adjacent to each other, overlap each other is an intersection region C. The intersection region C is a region of the piezoelectric layer 6 defined by the configuration of the IDT electrode 12. That is, the portion of the piezoelectric layer 6 where the IDT electrode 12 is provided includes the intersection region C. In the intersection region C, a 1/2 harmonic wave is excited.

When the wavelength defined by the electrode finger pitch of the IDT electrode 12 is defined as λ, the wavelength λ is the wavelength of the fundamental wave. On the other hand, the wavelength of the 1/2 harmonic wave is approximately twice the wavelength λ. In addition, the electrode finger pitch is the center-to-center distance of the first electrode finger 18 and the second electrode finger 19, which are adjacent to each other, in the electrode finger orthogonal direction. For example, when the electrode finger pitch is defined as p, λ=2p.

As illustrated in FIG. 1, the piezoelectric layer 6 includes a first region A and a second region B. The first region A and the second region B are in a relationship in which the polarization directions are inverted from each other. In the present specification, the relationship in which the polarization directions are inverted from each other at two portions means that the acoustic properties of the crystal are the same at the two portions, and only the polarization directions are different from each other by approximately 180°. The difference in the polarization direction between the first region A and the second region B can be evaluated by using, for example, a scanning nonlinear dielectric constant microscope (SNDM) or the like.

The fact that the crystals have the same acoustic properties means that the crystal structures are substantially the same. Whether or not the crystal structures are the same can be determined, for example, by confirming the crystal structure by X-ray diffraction (XRD) or by confirming the polarization state by a nonlinear dielectric constant microscope.

The relationship in which the polarization directions are completely inverted from each other at the two portions is equivalent to the fact that the absolute value of the difference of θ in the Euler angles (φ, θ, ψ) of the two portions is 180º. In the first region A and the second region B in the acoustic wave device 1, the angle defined by both of the polarization axes is within about 180°±5°, for example. The polarization directions may be different from each other in the first region A and the second region B.

In the present example embodiment, the Euler angles are (0°, 140°, 0°) in the first region A. In the second region B, the polarization direction is completely inverted with respect to the first region A. Therefore, in the second region B, the Euler angles are equivalently (0°, 320°, 0°).

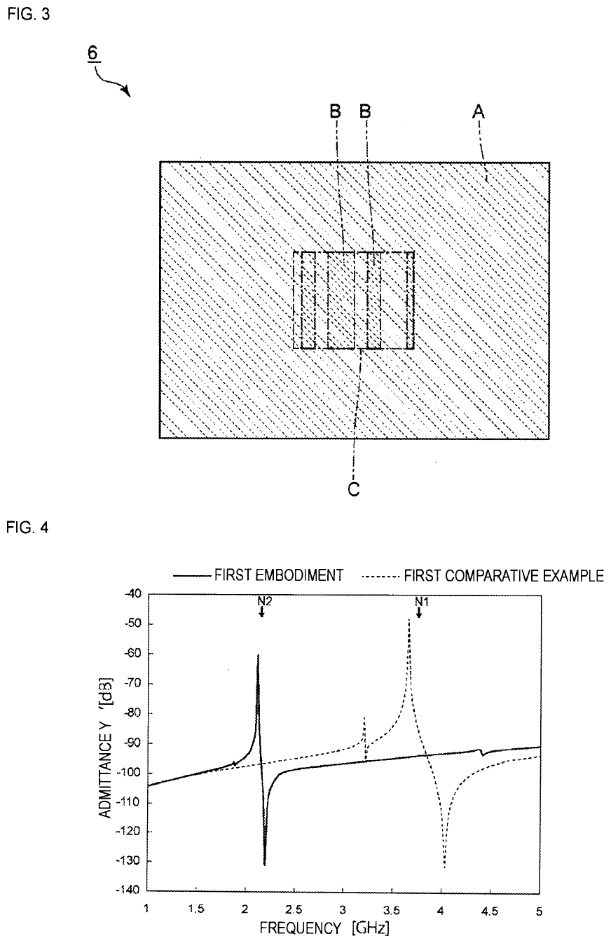

FIG. 3 is a schematic plan view of the piezoelectric layer, illustrating the disposition of the first region and the second region according to the first example embodiment. In FIG. 3, the first region A and the second region B are illustrated by hatching.

The first region A and the second region B are positioned at least in the intersection region C. Specifically, in the present example embodiment, the first region A is also positioned entirely outside the intersection region C. On the other hand, the second region B is positioned only in the intersection region C. That is, the second region B is surrounded by the first region A. However, the second region B may have a portion positioned at the outer side portion of the intersection region C.

Returning to FIG. 1, the first region A and the second region B are respectively positioned in the entirety of the piezoelectric layer 6 in the thickness direction. The first region A or the second region B may be positioned at a portion of the piezoelectric layer 6 in the thickness direction. In example embodiments of the present invention, the first region A and the second region B may be positioned at least on the main surface where the IDT electrode 12 is provided, in the piezoelectric layer 6.

The intersection region C includes a polarization change region. Specifically, the polarization change region is a region where the first region A and the second region B are alternately arranged in the electrode finger orthogonal direction. In the present example embodiment, the polarization change region is positioned in the entire intersection region C. However, the polarization change region may be positioned at a portion of the intersection region C in at least one of the electrode finger extending direction and the electrode finger orthogonal direction.

As described above, the first region A according to the present example embodiment illustrated in FIG. 3 includes a plurality of portions positioned in the intersection region C and a portion positioned outside the intersection region C. The plurality of portions of the first region A positioned within the intersection region C are coupled by portions positioned outside the intersection region C. Therefore, the first region A is one continuous region. However, in the present specification, each of the portions of the first region A, which faces each other, with the second region B interposed therebetween may be described as separate first regions A for convenience. As an actual configuration, the piezoelectric layer 6 may include the plurality of first regions A and the plurality of second regions B.

As illustrated in FIG. 1, the piezoelectric layer 6 includes first to eighth sections D1 to D8. More specifically, the piezoelectric layer 6 can be divided into a plurality of sections in the electrode finger orthogonal direction. It is assumed that each of the plurality of sections are in a range from a portion where the first electrode finger 18 or the second electrode finger 19 is provided to a portion where the first electrode finger 18 and the second electrode finger 19 are not provided. It is assumed that the number of electrode fingers provided in each section is only one in the plurality of first electrode fingers 18 and the plurality of second electrode fingers 19. The plurality of sections include the first to eighth sections D1 to D8.

The first to eighth sections D1 to D8 are arranged in order in the electrode finger orthogonal direction. Specifically, the first section D1, the second section D2, the third section D3, the fourth section D4, the fifth section D5, the sixth section D6, the seventh section D7, and the eighth section D8 are arranged in this order. The first to eighth sections D1 to D8 are positioned over the portion where the two pairs of the first electrode finger 18 and the second electrode finger 19 are provided.

More specifically, the first section D1 is a range from the portion where the first electrode finger 18 and the second electrode finger 19 are not provided to the portion where the leftmost first electrode finger 18 in FIG. 1 is provided. The second section D2 is a range from the portion where the first electrode finger 18 is provided to the portion where the first electrode finger 18 and the second electrode finger 19 are not provided. Therefore, the boundary between the first section D1 and the second section D2 is positioned at the portion where the first electrode finger 18 is provided. The first electrode finger 18 may be coupled to the input side of the signal potential, may be coupled to the output side of the signal potential, or may be coupled to the ground potential.

More specifically, the third section D3 is a range from the portion where the first electrode finger 18 and the second electrode finger 19 are not provided to the portion where the leftmost second electrode finger 19 in FIG. 1 is provided. The boundary between the second section D2 and the third section D3 is positioned at the portion where the first electrode finger 18 and the second electrode finger 19 are not provided. That is, when the portion between the first electrode finger 18 and the second electrode finger 19, which are adjacent to each other, is defined as an inter-electrode finger portion, the boundary between the second section D2 and the third section D3 is positioned in the inter-electrode finger portion.

The fourth section D4 is a range from the portion where the leftmost second electrode finger 19 is provided in FIG. 1 to the inter-electrode finger portion. The boundary between the third section D3 and the fourth section D4 is positioned at the portion where the second electrode finger 19 is provided. As described above, the first to fourth sections D1 to D4 are arranged side by side. In addition, the fifth to eighth sections D5 to D8 are also arranged in the same manner.

When the first to eighth sections D1 to D8 are defined as one set of areas, the piezoelectric layer 6 includes a plurality of areas. The plurality of areas are arranged continuously in the electrode finger orthogonal direction. That is, the eighth section D8 is sandwiched between the seventh section D7 and the first section D1. A boundary between the eighth section D8 and the first section D1 is positioned in the inter-electrode finger portion.

The first region A or the second region B is positioned in each section. Specifically, the first region A is positioned in the first section D1. The second region B is positioned in the second section D2. The first region A is positioned in the third section D3. The second region B is positioned in the fourth section D4. The second region B is positioned in the fifth section D5. The first region A is positioned in the sixth section D6. The second region B is positioned in the seventh section D7. The first region A is positioned in the eighth section D8.

Hereinafter, the first region A and the second region B positioned in the first to eighth sections D1 to D8 may be omitted. Specifically, the first region A is indicated as 1 and the second region B is indicated as 2, and the regions positioned in each section are indicated by dividing the region by a slash symbol. Then, the regions positioned in the first to eighth sections D1 to D8 are illustrated in order from the left side. In the present example embodiment, the disposition of the first region A and the second region B in the first to eighth sections D1 to D8 is 1/2/1/2/2/1/2/1. Such one set of areas is arranged continuously in the electrode finger orthogonal direction. Therefore, for example, the disposition of the first region A and the second region B in two continuous sets of areas is 1/2/1/2/2/1/2/1/1/2/1/2/2/1/2/1.

A feature of the present example embodiment is that, in the intersection region C, the polarization change region is configured by the first region A and the second region B, and in the polarization change region, the disposition of the first region A and the second region B is 1/2/1/2/2/1/2/1. As a result, an acoustic wave having a wavelength that is approximately twice the wavelength λ of the fundamental wave can be excited. That is, the 1/2 harmonic wave can be excited. Further, the fundamental wave can be suppressed. Therefore, the 1/2 harmonic wave can be preferably used for the operation of the acoustic wave device 1, and the fundamental wave as an unnecessary wave can be suppressed. This will be described below by comparing the present example embodiment and a first comparative example.

The first comparative example is different from the first example embodiment in that the piezoelectric layer does not include a region of which the polarization direction is inverted. In the first comparative example, the polarization direction of the piezoelectric layer is constant. The admittance frequency characteristics of the acoustic wave device 1 having the configuration of the first example embodiment and the acoustic wave device of the first comparative example are derived by a finite element method (FEM) simulation. Example design parameters of the acoustic wave device 1 having the configuration of the first example embodiment are as follows.

High acoustic velocity support substrate: Material . . . Si
Silicon oxide film: Material . . . SiO₂, thickness . . . 0.2λ
Piezoelectric layer: Material . . . rotated Y-cut LiNbO₃, thickness . . . 0.2λ, Euler angles of first region . . . (0°, 140°, 0°, Euler angles of second region . . . (0°, 320°, 0°)
IDT electrode: Material . . . Al, thickness . . . 0.1λ
Wavelength λ . . . 1 μm
Duty ratio . . . 0.5

The design parameters of the first comparative example are the same as those of the first example embodiment except that the piezoelectric layer does not have the second region. Therefore, the piezoelectric layer in the first comparative example has only the first region. The Euler angles of the piezoelectric layer are (0°, 140°, 0°).

FIG. 4 is a diagram illustrating admittance frequency characteristics in the first example embodiment and a first comparative example.

An arrow N1 in FIG. 4 indicates the frequency at which the fundamental wave is generated. More specifically, in the first example embodiment and the first comparative example, the acoustic velocity of the acoustic wave that propagates through the piezoelectric layer is approximately 4000 m/s. From the above design parameters, the wavelength of the fundamental wave is 1 μm. When the wavelength of any wave is defined as λn, the frequency is defined as f, and the acoustic velocity is defined as v, f=v/λn. From the expression, the frequency of the fundamental wave in the first example embodiment is approximately 4 GHz. As illustrated in FIG. 4, the fundamental wave is emphatically excited in the first comparative example. On the other hand, it can be seen that the fundamental wave is suppressed in the first example embodiment.

An arrow N2 in FIG. 4 indicates a frequency at which a 1/2 harmonic wave is generated. The frequency of the 1/2 harmonic wave is a frequency that exceeds 2 GHz. As illustrated in FIG. 4, no 1/2 harmonic wave is generated in the first comparative example. On the other hand, in the first example embodiment, it can be seen that the 1/2 harmonic wave is emphatically excited. Therefore, in the first example embodiment, the 1/2 harmonic wave can be preferably used in the operation of the acoustic wave device 1, and the fundamental wave as an unnecessary wave can be effectively suppressed.

The reason why the above effect in the first example embodiment can be obtained will be described below. First, for reference, it will be described that the fundamental wave is excited in the first comparative example and the second comparative example. In the first comparative example, the piezoelectric layer has only the first region, as described above. In the second comparative example, the polarization direction of the piezoelectric layer is inverted with respect to the polarization direction of the piezoelectric layer in the first comparative example. The piezoelectric layer according to the second comparative example has only a region corresponding to the second region in the first example embodiment.

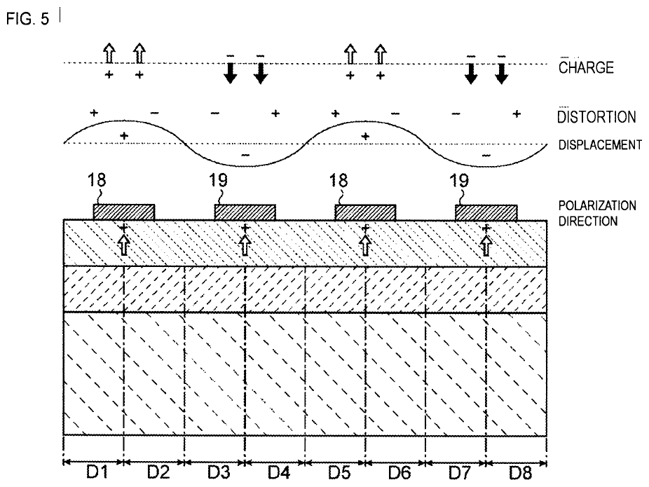

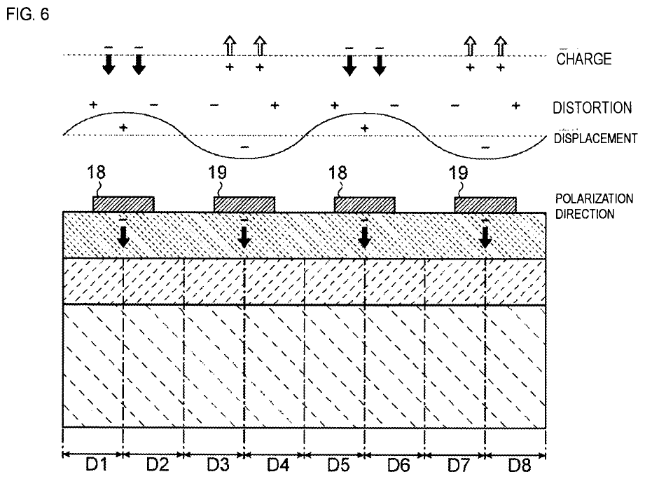

FIG. 5 is a schematic elevational cross-sectional view illustrating a vicinity of two pairs of electrode fingers according to the first comparative example, and is a view for describing that a fundamental wave is excited in the first comparative example. FIG. 6 is a schematic elevational cross-sectional view illustrating a vicinity of two pairs of electrode fingers according to the second comparative example, and is a view for describing that a fundamental wave is excited in the second comparative example.

In FIGS. 5 and 6, the polarization direction in the piezoelectric layer is schematically illustrated. In FIGS. 5 and 6, as the sign of the polarization direction, the sign of the main surface side where each electrode finger is provided of the piezoelectric layer is illustrated. In FIGS. 5 and 6, a displacement, and the accompanying distortion and charge when it is assumed that the fundamental wave is excited are schematically illustrated.

In the example illustrated in FIG. 5, the portion where each electrode finger is provided is positioned at the local maximum value or the local minimum value of the displacement. Therefore, for example, in FIG. 5, the portion where each electrode finger is provided includes a portion where the displacement inclination is the upper right diagonal and a portion where the displacement inclination is the lower right diagonal. Therefore, in FIG. 5, the charges generated at two portions included in each portion where each electrode finger is provided are illustrated. The same applies to diagrams illustrating that waves are excited or difficult to be excited, other than FIG. 5.

Simply, it can be said that a charge is generated by the displacement of the piezoelectric layer. Then, simply, the sign of the charge generated in the piezoelectric layer can be represented by the product of the sign of the polarization direction of the piezoelectric layer and the direction of the displacement. As illustrated in FIG. 5, in the first comparative example, the sign of the polarization direction is positive, and the sign of direction of the displacement is positive at the portion where the first electrode finger 18 is provided. Therefore, the sign of the charge generated at the portion where the first electrode finger 18 is provided is positive. The sign of the polarization direction is also positive at the portion where the second electrode finger 19 is provided. At the portion where the second electrode finger 19 is provided, the displacement direction is negative. Therefore, the sign of the charge generated at the portion where the second electrode finger 19 is provided is negative.

As described above, the charge generated at the portion where the first electrode finger 18 is provided and the charge generated at the portion where the second electrode finger 19 is provided have different signs from each other. Therefore, the first electrode finger 18 and the second electrode finger 19 have a potential difference. That is, the excitation of the fundamental wave matches the fact that the first electrode finger 18 and the second electrode finger 19 have the potential difference. Therefore, in the comparative example, the fundamental wave is emphatically excited.

Distortion is generated in the piezoelectric layer by the displacement of the piezoelectric layer. As illustrated in FIG. 5, the sign of the distortion is the sign of the value obtained by differentiating the displacement by the position. Specifically, the sign of a value of dy/dx when the displacement is defined as y and the position is defined as x is the sign of the distortion. More specifically, when the right side in FIG. 5 is defined as a positive direction of the position, the sign of the distortion is positive when a curve representing the displacement has an inclination diagonally to the upper right. When the curve representing the displacement in FIG. 5 has an inclination diagonally to the lower right, the sign of the distortion is negative. The same applies to diagrams illustrating that waves are excited or difficult to be excited, other than FIG. 5.

The generation of a charge in the piezoelectric layer is precisely caused by the distortion generated in the piezoelectric layer. For example, at the portion of the first electrode finger 18 provided in the first section D1, the sign of the distortion and the sign of the charge are the same. Similarly, at the portion of the electrode finger provided in an odd-numbered section other than the first section D1, the sign of the distortion and the sign of the charge are the same. On the other hand, at the portion of the electrode finger provided in an even-numbered section, such as the second section D2, the sign of the distortion and the sign of the charge are opposite to each other.

As illustrated in FIG. 6, in the second comparative example, the sign of the charge generated at the portion where the first electrode finger 18 is provided is negative. The sign of the charge generated at the portion where the second electrode finger 19 is provided is positive. Therefore, the first electrode finger 18 and the second electrode finger 19 have a potential difference. Accordingly, the excitation of the fundamental wave matches the fact that the first electrode finger 18 and the second electrode finger 19 have the potential difference. Therefore, in the second comparative example, the fundamental wave is emphatically excited.

As described above, in the second comparative example, the polarization direction of the piezoelectric layer is inverted with respect to the polarization direction of the piezoelectric layer in the first comparative example. Accordingly, as can be understood by comparing FIGS. 5 and 6, in the second comparative example, the relationship between the sign of the distortion and the sign of the charge is inverted with respect to the first comparative example. From this, when the sign of the charge is used as a reference, the inversion of the polarization direction and the inversion of the sign of the distortion are equivalent to each other. Based on this, the concept of effective distortion, which is the product of the sign of the polarization direction and the sign of the distortion, can be introduced.

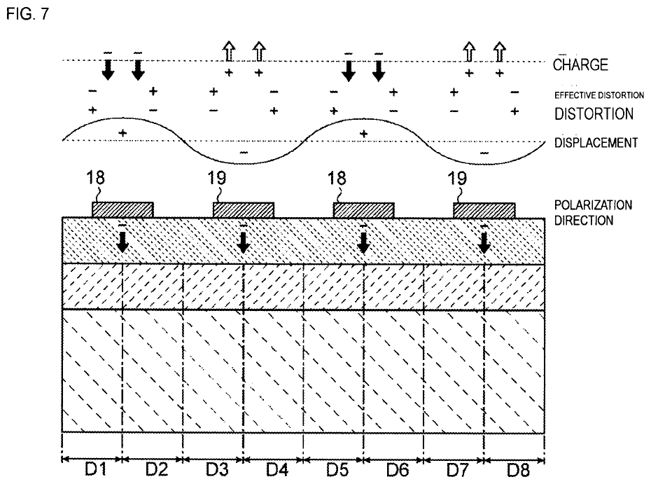

FIG. 7 is a schematic elevational cross-sectional view illustrating a relationship between an effective distortion and a charge, in the second comparative example.

As illustrated in FIG. 7, the sign of the polarization direction of the piezoelectric layer is negative in the second comparative example. Therefore, the sign of the effective distortion is a sign opposite to the sign of the distortion. On the other hand, in the first comparative example, the polarization direction of the piezoelectric layer is positive. Therefore, the sign of the effective distortion is the same as the sign of the distortion. Therefore, it can be said that the sign of the distortion illustrated in FIG. 5 indicates the sign of the effective distortion. As can be seen by comparing FIGS. 5 and 7, the relationship between the sign of the effective distortion and the sign of the charge is the same in the first comparative example and the second comparative example. That is, the generated charge can be evaluated by using the effective distortion.

Furthermore, it will be described below that the 1/2 harmonic wave can be excited and the fundamental wave can be suppressed in the first example embodiment.

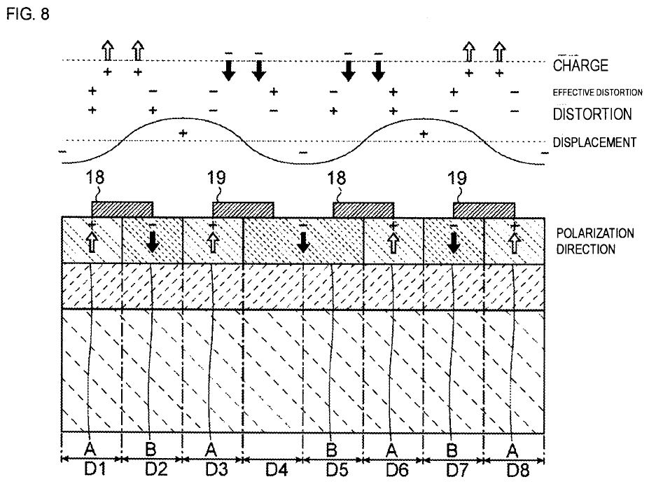

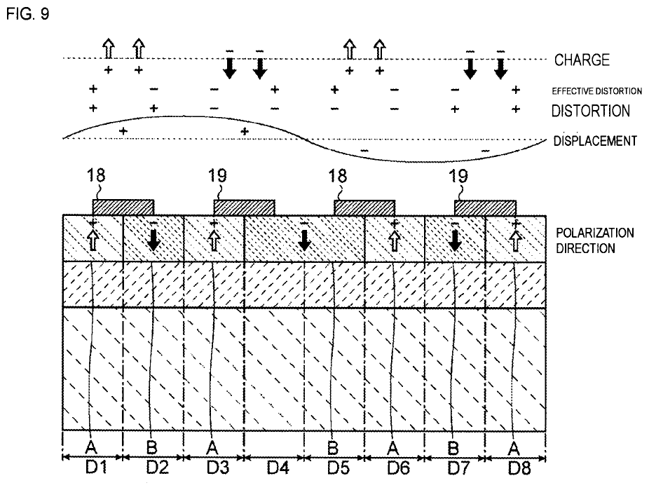

FIG. 8 is a schematic elevational cross-sectional view illustrating a vicinity of two pairs of electrode fingers of the acoustic wave device according to the first example embodiment, and is a view for describing that the fundamental wave is difficult to be excited in the first example embodiment. FIG. 9 is a schematic elevational cross-sectional view illustrating a vicinity of two pairs of electrode fingers of the acoustic wave device according to the first example embodiment, and is a view for describing that a 1/2 harmonic wave is excited in the first example embodiment.

As illustrated in FIG. 8, in the first example embodiment, the disposition of the first region A and the second region B in the polarization change region is 1/2/1/2/2/1/2/1. In this configuration, when it is assumed that the fundamental wave is excited, the sign of the charge generated at the portion where the first electrode finger 18 is provided is the same sign as the sign of the charge generated at the portion where one of the two second electrode fingers 19 adjacent to the first electrode finger 18 is provided. Therefore, a portion where the first electrode finger 18 and the second electrode finger 19, which are adjacent to each other, have no potential difference is generated. That is, there is a portion where the fact that the fundamental wave is excited and the fact that the first electrode finger 18 and the second electrode finger 19 have the potential difference do not match. Therefore, in the first example embodiment, the excitation of the fundamental wave can be effectively suppressed.

The first region A and the second region B do not necessarily have to be in a relationship in which the polarization directions are inverted from each other. In the first region A and the second region B, the polarization directions may be different from each other. In this case, the potential difference between the first electrode finger 18 and the second electrode finger 19 due to the excitation of the fundamental wave is reduced. Therefore, the intensity of the response due to the fundamental wave can be reduced. That is, the fundamental wave can be suppressed.

On the other hand, as illustrated in FIG. 9, when it is assumed that the 1/2 harmonic wave is excited, the charge generated at the portion where the first electrode finger 18 is provided and the charge generated at the portion where the second electrode finger 19 is provided have different signs from each other. Therefore, the first electrode finger 18 and the second electrode finger 19 have a potential difference. That is, the excitation of the 1/2 harmonic wave matches the fact that the first electrode finger 18 and the second electrode finger 19 have the potential difference. Therefore, in the first example embodiment, the 1/2 harmonic wave is emphatically excited.

As described above, the relationship between the frequency f of any wave, the acoustic velocity v, and the wavelength λn is represented by f=v/An. The wavelength λn is defined by the electrode finger pitch of the IDT electrode. Therefore, in the related art, when using low frequency waves, it is necessary to widen the electrode finger pitch of the IDT electrode. Therefore, it is necessary to increase the size of the acoustic wave device. On the other hand, in the first example embodiment, a low frequency acoustic wave such as a 1/2 harmonic wave can be preferably used even when the electrode finger pitch of the IDT electrode is not enlarged. Therefore, in the first example embodiment, the low frequency acoustic wave can be preferably used without increasing the size of the acoustic wave device 1.

When the piezoelectric layer 6 having the first region A and the second region B in the first example embodiment illustrated in FIG. 1 is obtained, for example, film formation processing may be performed on the wafer corresponding to the piezoelectric layer having only the first region A. As a result, the piezoelectric layer 6 including the first region A and the second region B may be formed. In this case, for example, the crystallinity at a portion of the surface of the wafer may be disturbed in advance by surface treatment such as ion beam irradiation or plasma treatment. Alternatively, the surface diffusion may be reduced by lowering a film formation temperature when performing film formation processing on the wafer. Through these, the film having the second region B can be grown. For example, by forming a resist pattern during the surface treatment, the disposition of the first region A and the second region B can be adjusted.

Alternatively, when film formation is performed by sputtering, a milling effect due to self-bias may be used. Accordingly, the preferential orientation surface can be controlled, and the polarization direction of the second region B can be easily inclined with respect to the polarization direction of the first region A. More specifically, for example, when LiNbO₃ is used as the wafer material, ion beam irradiation may be performed from a normal direction of the main surface of the wafer. Accordingly, a film in which the crystal c axis direction is inclined from the normal direction can be easily grown. As a result, a film having an inclined polarization direction can be formed.

After the second region B is formed in the wafer, the second region B may be positioned on the entirety of the wafer in the thickness direction, by adjusting the thickness of the wafer or the like. After that, the plurality of piezoelectric layers 6 may be obtained by dividing the wafer.

Hereinafter, a preferable configuration of the first example embodiment will be described.

It is preferable that the angle defined by the polarization axis in the first region A and the polarization axis in the second region B is within a range of about 180°±5°, for example. In this case, as described above, the first region A and the second region B are in a relationship in which the polarization directions are inverted from each other. Accordingly, the 1/2 harmonic wave can be emphatically excited, and the fundamental wave can be effectively suppressed.

As illustrated in FIG. 1, in the first example embodiment, the boundary between the first section D1 and the second section D2 is positioned at the portion where the first electrode finger 18 is provided. Specifically, in the first example embodiment, the boundary is positioned at the center of the electrode finger in the electrode finger orthogonal direction. That is, when a distance in the electrode finger orthogonal direction between the boundary and the center of the electrode finger in the electrode finger orthogonal direction is defined as L1, and an electrode finger pitch of a portion where the electrode finger is positioned is defined as p1, L1/p1=0.

The distance L1 and the electrode finger pitch p1 can be similarly defined at the boundary between other sections and other electrode fingers. More specifically, in the first example embodiment, the distance L1 and the electrode finger pitch p1 can be defined at the boundary between the third section D3 and the fourth section D4 and the second electrode finger 19. In addition, at the boundary between the fifth section D5 and the sixth section D6 and the first electrode finger 18, and the boundary between the seventh section D7 and the eighth section D8 and the second electrode finger 19, the distance L1 and the electrode finger pitch p1 can be defined.

When the boundary between the sections is positioned at the portion where any electrode finger is provided, and when the electrode finger is adjacent to other two electrode fingers, the average electrode finger pitches of three continuous electrode fingers with the electrode finger as the center is defined as an electrode finger pitch p1. However, in the first example embodiment, the electrode finger pitch is constant.

It is preferable that L1/p1<about 0.1 in at least one set of electrode fingers and a boundary positioned at the portion where the electrode fingers are provided. In this case, the 1/2 harmonic wave can be more reliably excited, and the fundamental wave can be more reliably suppressed. It is preferable that L1/p1<about 0.1 in all of the electrode fingers and a boundary positioned at the portion where the electrode fingers are provided. Accordingly, the 1/2 harmonic wave can be more reliably excited, and the fundamental wave can be more reliably suppressed. It is further preferable that L1/p1=0 as in the first example embodiment. Accordingly, the 1/2 harmonic wave can be more reliably and emphatically excited, and the fundamental wave can be more reliably and effectively suppressed.

As illustrated in FIG. 1, in the first example embodiment, the boundary between the second section D2 and the third section D3 is positioned at the inter-electrode finger portion. Specifically, in the first example embodiment, the boundary is positioned at the center of the inter-electrode finger portion in the electrode finger orthogonal direction. That is, when a distance in the electrode finger orthogonal direction between the boundary and the center of the inter-electrode finger portion in the electrode finger orthogonal direction is defined as L2, and an electrode finger pitch of a portion where the inter-electrode finger portion is positioned is defined as p2, L2/p2=0.

The distance L2 and the electrode finger pitch p2 can be similarly defined at the boundary between other sections and other electrode fingers. More specifically, in the first example embodiment, the distance L2 and the electrode finger pitch p2 can be defined at the boundary between the fourth section D4 and the fifth section D5 and the inter-electrode finger portion. In addition, the distance L2 and the electrode finger pitch p2 can be defined at the boundary between the sixth section D6 and the seventh section D7 and the inter-electrode finger portion.

It is preferable that L2/p2<about 0.1 in at least one set of the inter-electrode finger portions and the boundary positioned in the inter-electrode finger portion. In this case, the 1/2 harmonic wave can be more reliably excited, and the fundamental wave can be more reliably suppressed. It is preferable that L2/p2<about 0.1 in all of the inter-electrode finger portions and the boundaries positioned in the inter-electrode finger portions. Accordingly, the 1/2 harmonic wave can be more reliably excited, and the fundamental wave can be more reliably suppressed. It is further preferable that L2/p2=0 as in the first example embodiment. Accordingly, the 1/2 harmonic wave can be more reliably and emphatically excited, and the fundamental wave can be more reliably and effectively suppressed.

It is preferable that the piezoelectric substrate 2 is a laminated substrate including the high acoustic velocity layer and the piezoelectric layer 6. It is more preferable that the piezoelectric substrate 2 is a laminated substrate in which the high acoustic velocity layer, the low acoustic velocity film, and the piezoelectric layer 6 are laminated in this order. In the first example embodiment, the high acoustic velocity layer is the high acoustic velocity support substrate 4, and the low acoustic velocity film is the silicon oxide film 5. When the piezoelectric substrate 2 has a laminated configuration as described above, the energy of the 1/2 harmonic wave can be effectively confined on the piezoelectric layer 6 side.

It is preferable that the low acoustic velocity film is the silicon oxide film 5, as in the first example embodiment. As a result, the absolute value of the temperature coefficient of frequency (TCF) of the acoustic wave device 1 can be reduced. Accordingly, the frequency temperature characteristics of the acoustic wave device 1 can be improved.

However, as the material of the low acoustic velocity film, for example, glass, silicon oxide, silicon oxynitride, lithium oxide, tantalum oxide, or a dielectric such as a compound obtained by adding fluorine, carbon, or boron to silicon oxide, or a material of which the main components are above materials can also be used.

In the present specification, the main component means a component that accounts for more than 50% by weight. The material of the main component may exist in any one state of single crystal, polycrystal, and amorphous, or a mixed state thereof.

In the first example embodiment, the piezoelectric layer 6 is provided directly on the silicon oxide film 5 as the low acoustic velocity film. The piezoelectric layer 6 may be indirectly provided on the low acoustic velocity film with a piezoelectric layer other than the piezoelectric layer 6, a dielectric layer interposed therebetween, or the like.

As a material of the high acoustic velocity support substrate 4 which is a high acoustic velocity layer, silicon is used. However, the material of the high acoustic velocity layer is not limited to the above. Examples of materials for the high acoustic velocity layer include piezoelectric materials such as aluminum nitride, lithium tantalate, lithium niobate, and quartz crystal, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, semiconductors such silicon, and materials of which main components are the above materials. The spinel includes an aluminum compound containing one or more elements selected from Mg, Fe, Zn, Mn, and the like, and oxygen. Examples of the spinel include MgAl₂O₄, FeAl₂O₄, ZnAl₂O₄, and MnAl₂O₄.

In the first example embodiment, the piezoelectric layer 6 is indirectly provided on the high acoustic velocity support substrate 4 as a high acoustic velocity layer, with the low acoustic velocity film interposed therebetween. For example, the piezoelectric layer 6 may be indirectly provided on the high acoustic velocity layer with a piezoelectric layer other than the piezoelectric layer 6 or a dielectric film other than the low acoustic velocity film interposed therebetween. Alternatively, the piezoelectric layer 6 may be provided directly on the high acoustic velocity layer.

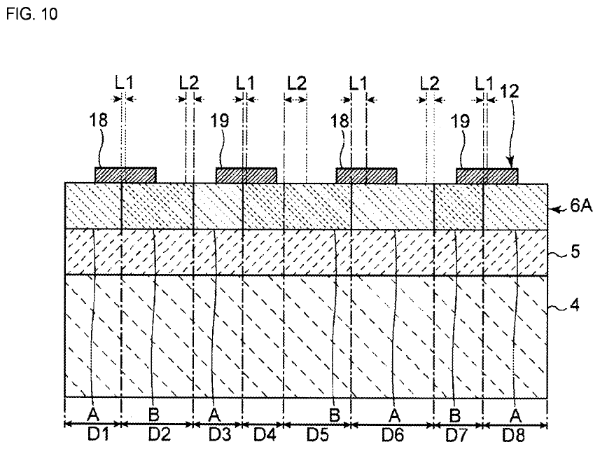

In the acoustic wave device 1 of the first example embodiment, the boundary between any one of the sections is also positioned at one of the center of the portion where the electrode fingers are provided in the electrode finger orthogonal direction and the center of the inter-electrode finger portion in the electrode finger orthogonal direction. Therefore, one of L1=0 and L2=0 is satisfied at the boundary between any sections. The disposition of the boundaries between the respective sections is not limited to the above. For example, in a piezoelectric layer 6A of the first modification example illustrated in FIG. 10, one of L1>0 and L2>0 is satisfied at the boundaries between all of the sections. In the present modification example, similarly to the first example embodiment, the 1/2 harmonic wave can be excited and the fundamental wave can be suppressed.

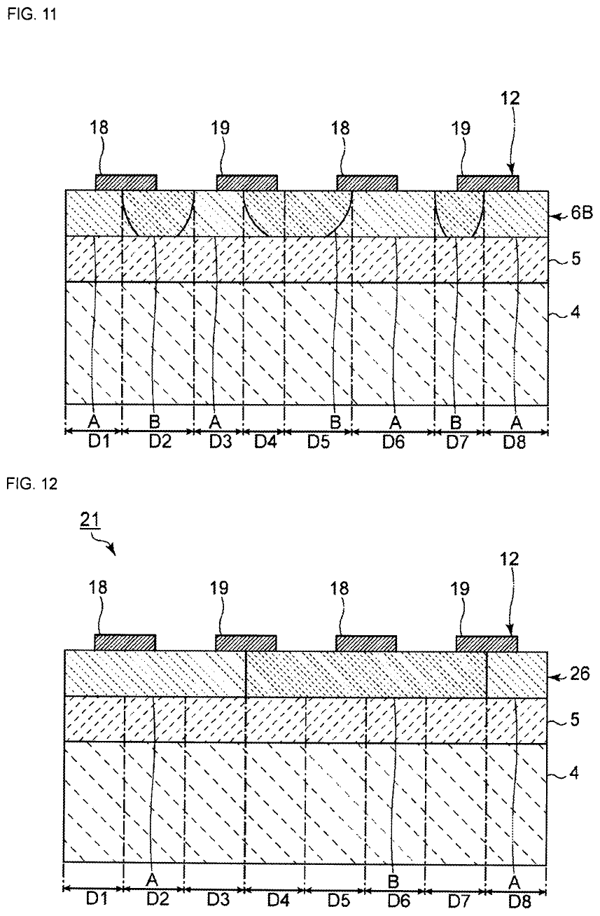

In the first example embodiment and the first modification example thereof, the boundary between the first region A and the second region B extends in the normal direction of the main surface of the piezoelectric layer. However, the disposition of the boundary between the first region A and the second region B is not limited to the above. For example, in a piezoelectric layer 6B according to the second modification example of the first example embodiment illustrated in FIG. 11, the boundary between the first region A and the second region B has a curved shape in the cross section along the electrode finger orthogonal direction. Specifically, the dimension of the second region B along the electrode finger orthogonal direction becomes smaller as the distance from the main surface on which the IDT electrode 12 is provided increases in the thickness direction of the piezoelectric layer 6B. Therefore, the boundary between the first region A and the second region B is disposed in the section where the second region B is positioned.

More specifically, on the main surface of the piezoelectric layer 6B where the IDT electrode 12 is provided, the second region B reaches the entire second section D2, fourth section D4, fifth section D5, and seventh section D7. However, the second region B is laminated on the first region A in the vicinity of the boundary between the second section D2 and the adjacent section, in the second section D2. The same applies to the fourth section D4, the fifth section D5, and the seventh section D7. On the other hand, only the first region A is positioned in the first section D1, the third section D3, the sixth section D6, and the eighth section D8.

The first region A and the second region B may be positioned at least on the main surface where the IDT electrode 12 is provided, in the piezoelectric layer 6B. In addition, also in the present modification example, similarly to the first example embodiment, the disposition of the first region A and the second region B in the polarization change regions is 1/2/1/2/2/1/2/1. Accordingly, in the present modification example, the 1/2 harmonic wave can be excited and the fundamental wave can be suppressed.

In addition, in the present modification example, similarly to the first modification example, one of L1>0 and L2>0 is satisfied at the boundaries between all of the sections.

The configuration of the boundaries between the respective sections in the first modification example and the configuration of the boundaries between the first region A and the second region B in the second modification example can be used in other aspects of example embodiments of the present invention.

As described above, the polarization change region is a region where the first region A and the second region B are alternately arranged in the electrode finger orthogonal direction. The polarization change region may be positioned in at least a portion of the intersection region C illustrated in FIG. 2 in the electrode finger extending direction. Each region positioned at the portion where the electrode finger is provided may overlap at least a portion of the portion of the electrode finger positioned in the intersection region C in plan view. A specific example will be described below. In addition, in the present specification, a plan view means that an acoustic wave device is viewed in a direction corresponding to the upper side in FIG. 1. In FIG. 1, for example, on the high acoustic velocity support substrate 4 side and the piezoelectric layer 6 side, the piezoelectric layer 6 side is the upper side.

For example, in the first section D1 and the like illustrated in FIG. 1, the first region A may overlap at least a portion of the portion of the first electrode finger 18 positioned in the intersection region C in the electrode finger extending direction, in plan view.

In the third section D3 and the like, the first region A may overlap at least a portion of the portion of the second electrode finger 19 positioned in the intersection region C in the electrode finger extending direction, in plan view.

Similarly, for example, in the second section D2 and the like, the second region B may overlap at least a portion of the portion of the first electrode finger 18 positioned in the intersection region C in the electrode finger extending direction, in plan view. In the fourth section D4 and the like, the second region B may overlap at least a portion of the portion of the second electrode finger 19 positioned in the intersection region C in the electrode finger extending direction, in plan view.

As schematically illustrated in FIG. 3, the piezoelectric layer 6 includes one first region A and a plurality of second regions B. However, the piezoelectric layer 6 may have a plurality of first regions A and a plurality of second regions B. For example, some second regions B may surround one first region A in the plurality of first regions A. In this case, specifically, for example, some second regions B have a plurality of portions positioned in the intersection region C and a plurality of portions positioned outside the intersection region C. In addition, the plurality of portions of the second region B positioned within the intersection region C are coupled by portions positioned outside the intersection region C. One first region A is surrounded by the second region B.

Incidentally, a dielectric film may be provided on the piezoelectric layer 6. Accordingly, since the IDT electrode 12 is protected by the dielectric film, the IDT electrode 12 is less likely to be damaged. As the material of the dielectric film, for example, silicon oxide, silicon nitride, silicon oxynitride, or the like can be used. A configuration in which the dielectric film is provided can be used in other aspects of example embodiments of the present invention.

A piezoelectric layer other than the piezoelectric layer 6 or a dielectric layer may be provided between the piezoelectric layer 6 and the IDT electrode 12. In this case, the specific bandwidth of the acoustic wave device can be adjusted by adjusting the thickness of the piezoelectric layer or the dielectric layer, or the like. A configuration in which the piezoelectric layer or the dielectric layer is provided can be used in other aspects of example embodiments of the present invention.

When a total of dimensions along the electrode finger orthogonal direction of the first region A is defined as E1 and a total of dimensions along the electrode finger orthogonal direction of the second region B is defined as E2 in the first to eighth sections D1 to D8, in the first example embodiment, E2/E1=1. However, the present disclosure is not limited thereto. However, it is preferable that E2/E1 is within a range of about 1+0.1. Accordingly, the 1/2 harmonic wave can be more reliably and emphatically excited, and the fundamental wave can be more reliably and effectively suppressed. It is more preferable that E2/E1=1 as in the first example embodiment. Accordingly, the 1/2 harmonic wave can be more reliably and emphatically excited, and the fundamental wave can be more reliably and effectively suppressed.

In the first example embodiment, the electrode finger pitch of the IDT electrode 12 is constant. In example embodiments of the present invention, the IDT electrode 12 may include a plurality of portions having different electrode finger pitches. For example, in the IDT electrode 12, the electrode finger pitch may be random. In this case, E2/E1 is preferably a value based on a ratio of the center-to-center distance of the adjacent first electrode fingers 18 in the electrode finger orthogonal direction and the center-to-center distance of adjacent second electrode fingers 19 in the electrode finger orthogonal direction. Specifically, when the center-to-center distance of adjacent first electrode fingers 18 in the electrode finger orthogonal direction is defined as p3 and the center-to-center distance of adjacent second electrode fingers 19 in the electrode finger orthogonal direction is defined as p4, (p4/p3)/(E2/E1) is preferably in a range within about 1±0.1, for example. Accordingly, the 1/2 harmonic wave can be more reliably and emphatically excited, and the fundamental wave can be more reliably suppressed.

The width of the electrode fingers of the IDT electrode 12 in the first example embodiment is constant. However, in example embodiments of the present invention, the plurality of electrode fingers of the IDT electrode 12 may include electrode fingers having different widths. The width of the electrode finger is a dimension of the electrode finger along an electrode finger orthogonal direction.

Each of the above-described preferable examples and the like can also be applied to an aspect of an example embodiment of the present invention in which the disposition of the first region A and the second region B in the polarization change region is other than 1/2/1/2/2/1/2/1.

FIG. 12 is a schematic elevational cross-sectional view illustrating a vicinity of two pairs of electrode fingers of an acoustic wave device according to the second example embodiment.

The present example embodiment is different from the first example embodiment in that the disposition of the first region A and the second region B in the polarization change region of the piezoelectric layer 26 is 1/1/1/2/2/2/2/1. An acoustic wave device 21 of the present example embodiment has the same configuration as the acoustic wave device 1 of the first example embodiment in other respects than the above.

Similarly to the first example embodiment, in the present example embodiment, the 1/2 harmonic wave can be excited and the fundamental wave can be suppressed. This will be described below by comparing the present example embodiment and the first comparative example. The first comparative example is the same as the first comparative example according to the comparison in FIG. 4. That is, in the first comparative example, the polarization direction of the piezoelectric layer is constant.

The admittance frequency characteristics of the acoustic wave device 21 having the configuration of the second example embodiment and the acoustic wave device of the first comparative example are derived by a FEM simulation. Example design parameters of the acoustic wave device 21 having the configuration of the second example embodiment are as follows.

High acoustic velocity support substrate: Material . . . Si
Silicon oxide film: Material . . . SiO₂, thickness . . . 0.2λ
Piezoelectric layer: Material . . . rotated Y-cut LiNbO₃, thickness . . . 0.2λ, Euler angles of first region . . . (0°, 140°, 0°), Euler angles of second region . . . (0°, 320°, 0°)
IDT electrode: Material . . . Al, thickness . . . 0.1λ
Wavelength λ . . . 1 μm
Duty ratio . . . 0.5

The design parameters of the first comparative example are the same as those of the second example embodiment except that the piezoelectric layer does not have the second region. Therefore, the piezoelectric layer in the first comparative example has only the first region. The Euler angles of the piezoelectric layer are (0°, 140°, 0°).

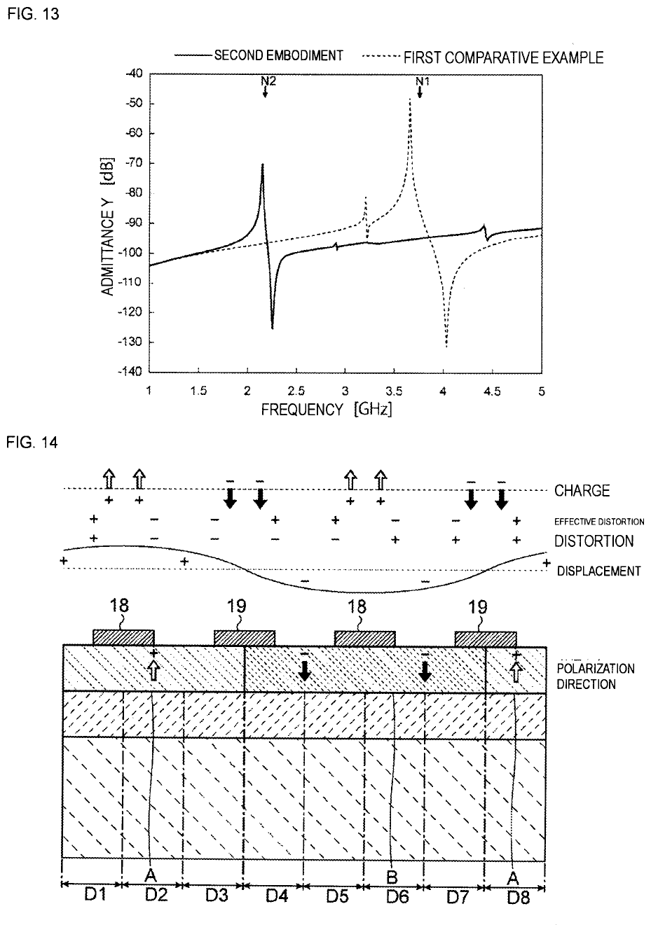

FIG. 13 is a diagram illustrating admittance frequency characteristics in the second example embodiment and the first comparative example.

As illustrated by the arrow N1 in FIG. 13, it can be seen that the fundamental wave is suppressed in the second example embodiment. Then, as illustrated by an arrow N2 in FIG. 13, it can be seen that the 1/2 harmonic wave is emphatically excited in the second example embodiment. Therefore, in the second example embodiment, the 1/2 harmonic wave can be preferably used in the operation of the acoustic wave device 21, and the fundamental wave as an unnecessary wave can be effectively suppressed. On the other hand, in the first comparative example, the fundamental wave is emphatically excited, and the 1/2 harmonic wave is not generated.

FIG. 14 is a schematic elevational cross-sectional view illustrating a vicinity of two pairs of electrode fingers of the acoustic wave device according to the second example embodiment, and is a view for describing that a 1/2 harmonic wave is excited in the second example embodiment.

On the other hand, as illustrated in FIG. 14, when it is assumed that the 1/2 harmonic wave is excited, the charge generated at the portion where the first electrode finger 18 is provided and the charge generated at the portion where the second electrode finger 19 is provided have different signs from each other. Therefore, the first electrode finger 18 and the second electrode finger 19 have a potential difference. That is, the excitation of the 1/2 harmonic wave matches the fact that the first electrode finger 18 and the second electrode finger 19 have the potential difference. Therefore, in the second example embodiment, the 1/2 harmonic wave is emphatically excited.

The boundary between the first section D1 and the second section D2 is preferably positioned at the portion where the first electrode finger 18 is provided. In this case, the first region A and the second region B are disposed as illustrated in FIG. 12. Specifically, the disposition of the first region A and the second region B in the polarization change regions is 1/1/1/2/2/2/2/1. Accordingly, the 1/2 harmonic wave can be more reliably and emphatically excited, and the fundamental wave can be more reliably suppressed. However, as described above, the first electrode finger 18 may be coupled to the input side of the signal potential, may be coupled to the output side of the signal potential, or may be coupled to the ground potential.

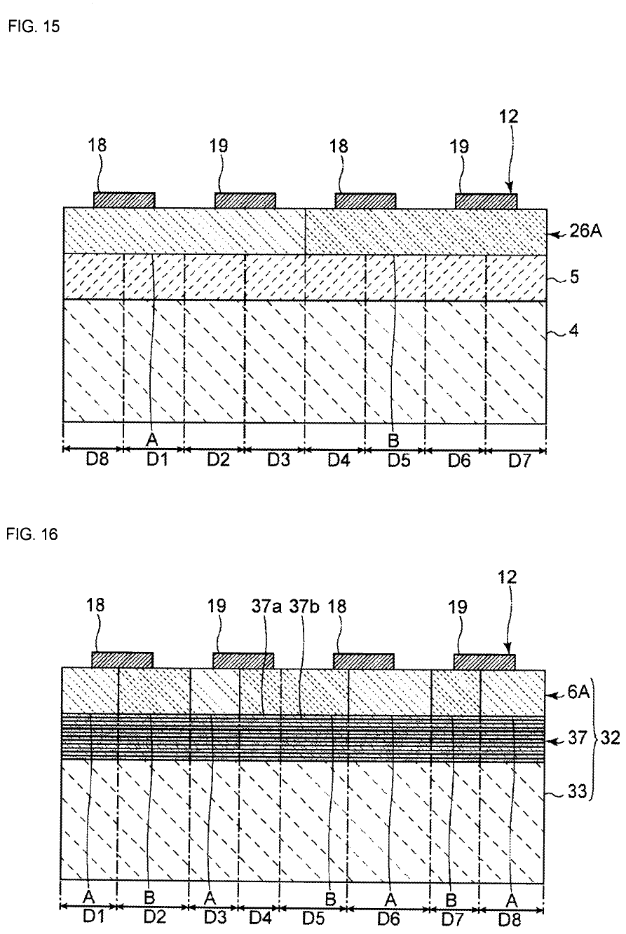

In addition, the boundary between the first section D1 and the second section D2 may be positioned in the inter-electrode finger portion. In this case, the disposition of the first to eighth sections D1 to D8 is a disposition shifted from the disposition illustrated in FIG. 12 by, for example, one section to the right side in FIG. 12. That is, as in the modification example of the second example embodiment illustrated in FIG. 15, the leftmost section in FIG. 15 is the eighth section D8, and the first to seventh sections D1 to D7 are arranged on the right side of the eighth section D8 in this order.

At the portion illustrated in FIG. 15, the disposition of the first region A and the second region B in the polarization change region is apparently 1/1/1/1/2/2/2/2. However, also in the piezoelectric layer 26A of the present modification example, similarly to the second example embodiment, the disposition of the first region A and the second region B in the first to eighth sections D1 to D8 is 1/1/1/2/2/2/2/1. In the present modification example, the 1/2 harmonic wave can be excited and the fundamental wave can be suppressed.

Hereinafter, the third to fifth example embodiments will be described as examples different in the laminated structure of the piezoelectric substrate from the first example embodiment and the second example embodiment. In the third to fifth example embodiments, the piezoelectric layer is configured similarly to that of the first modification example of the first example embodiment illustrated in FIG. 10. The acoustic wave device of the third to fifth example embodiments has the same configuration as the acoustic wave device 1 of the first example embodiment in other respects than the above.

In the third to fifth example embodiments, the disposition of the first region and the second region in the of the piezoelectric layer is polarization change region 1/2/1/2/2/1/2/1. Accordingly, similarly to the first example embodiment, the 1/2 harmonic wave can be excited and the fundamental wave can be suppressed. Therefore, the 1/2 harmonic wave can be preferably used for the operation of the acoustic wave device, and the fundamental wave as an unnecessary wave can be suppressed.

FIG. 16 is a schematic elevational cross-sectional view illustrating a vicinity of two pairs of electrode fingers of an acoustic wave device according to the third example embodiment.

The piezoelectric substrate 32 of the present example embodiment has a support substrate 33, an acoustic reflection film 37, and a piezoelectric layer 6A. The acoustic reflection film 37 is provided on the support substrate 33. A piezoelectric layer 6A is provided on the acoustic reflection film 37.

The support substrate 33 is a silicon substrate. The support substrate 33 in the present example embodiment is a high acoustic velocity support substrate as a high acoustic velocity layer. Therefore, as the material of the support substrate 33, the material of the above-described high acoustic velocity layer other than silicon can also be used. However, the support substrate 33 need not be the high acoustic velocity layer. As the material of the support substrate 33, for example, a material different from the material of the high acoustic velocity layer, such as resin, can be used.

The acoustic reflection film 37 is a multilayer body of a plurality of acoustic impedance layers. Specifically, the acoustic reflection film 37 includes a plurality of low acoustic impedance layers 37a and a plurality of high acoustic impedance layers 37b. The low acoustic impedance layer 37a is a layer having a relatively low acoustic impedance. On the other hand, the high acoustic impedance layer 37b is a layer having a relatively high acoustic impedance.

In an acoustic impedance layer, having a relatively low acoustic impedance means that the acoustic impedance layer is lower than that of an acoustic impedance layer adjacent to the acoustic impedance layer. In an acoustic impedance layer, having a relatively high acoustic impedance means that the acoustic impedance layer is higher than that of an acoustic impedance layer adjacent to the acoustic impedance layer. The low acoustic impedance layer 37a and the high acoustic impedance layer 37b are alternately laminated. In addition, the low acoustic impedance layer 37a is a layer positioned closest to the piezoelectric layer 6A side in the acoustic reflection film 37.

The acoustic reflection film 37 includes six low acoustic impedance layers 37a and six high acoustic impedance layers 37b, for example. However, the acoustic reflection film 37 may have at least one low acoustic impedance layer 37a and at least one high acoustic impedance layer 37b.

As the material of the low acoustic impedance layer 37a, for example, silicon oxide or aluminum can be used. As the material of the high acoustic impedance layer 37b, for example, a metal such as platinum or tungsten, or a dielectric such as aluminum nitride or silicon nitride can be used.

In the present example embodiment, the piezoelectric layer 6A is provided directly on the acoustic reflection film 37. However, the piezoelectric layer 6A may be indirectly provided on the acoustic reflection film 37 with a piezoelectric layer other than the piezoelectric layer 6A, a dielectric layer interposed therebetween, or the like. The piezoelectric substrate 32 may include a silicon oxide film as the dielectric layer. Alternatively, a silicon oxide film may be provided between the support substrate 33 and the acoustic reflection film 37. In the piezoelectric substrate 32, the piezoelectric layer 6A and the acoustic reflection film 37 may be laminated. As a result, the energy of the 1/2 harmonic wave can be effectively confined on the piezoelectric layer 6A side.

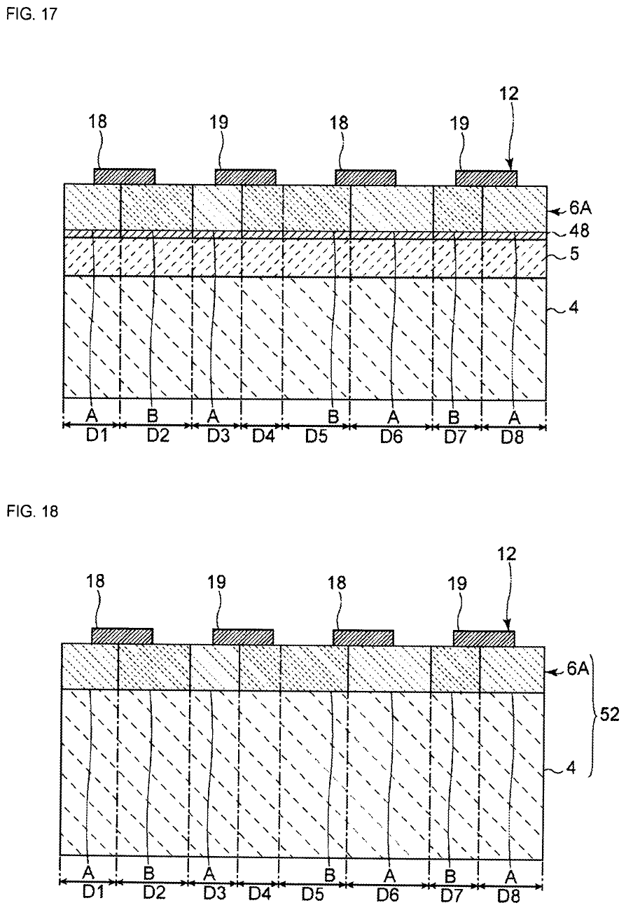

FIG. 17 is a schematic elevational cross-sectional view illustrating a vicinity of two pairs of electrode fingers of an acoustic wave device according to the fourth example embodiment.

In the present example embodiment, an electrode layer 48 is provided between the silicon oxide film 5 and the piezoelectric layer 6A. As a material of the electrode layer 48, an appropriate metal can be used.

The IDT electrode 12 and the electrode layer 48 face each other with the piezoelectric layer 6A interposed therebetween. Accordingly, the electrostatic capacitance can be increased. For example, the magnitude of the electrostatic capacitance can be adjusted by adjusting the thickness of the piezoelectric layer 6A, or the like. As a result, the specific bandwidth in the acoustic wave device can be adjusted.

In the present example embodiment, the piezoelectric layer 6A is provided directly on the electrode layer 48. However, the piezoelectric layer 6A may be indirectly provided on the electrode layer 48 with a piezoelectric layer other than the piezoelectric layer 6A, a dielectric layer interposed therebetween, or the like. In this case, the electrostatic capacitance of the acoustic wave device can be adjusted by adjusting the thickness of the piezoelectric layer or the dielectric layer, or the like. As a result, the specific bandwidth of the acoustic wave device can be adjusted.

For example, instead of the silicon oxide film 5, the acoustic reflection film 37 illustrated in FIG. 16 may be used.

FIG. 18 is a schematic elevational cross-sectional view illustrating a vicinity of two pairs of electrode fingers of an acoustic wave device according to the fifth example embodiment.

In a piezoelectric substrate 52 of the present example embodiment, the piezoelectric layer 6A is provided directly on the high acoustic velocity support substrate 4. In this case, similarly to the first example embodiment, the energy of the 1/2 harmonic wave can be effectively confined on the piezoelectric layer 6A side.

Even when the laminated configurations of the piezoelectric substrate are any one of the configurations illustrated in the third to fifth example embodiments, the disposition of the first region A and the second region B may be the same as the second example embodiment illustrated in FIG. 12. That is, the disposition of the first region A and the second region B in the polarization change regions may be 1/1/1/2/2/2/2/1. Alternatively, the boundary between the first section D1 and the second section D2 may be positioned in the inter-electrode finger portion. For example, similarly to the modification example of the second example embodiment illustrated in FIG. 15, the disposition of the first region A and the second region B may be apparently 1/1/1/1/2/2/2/2.

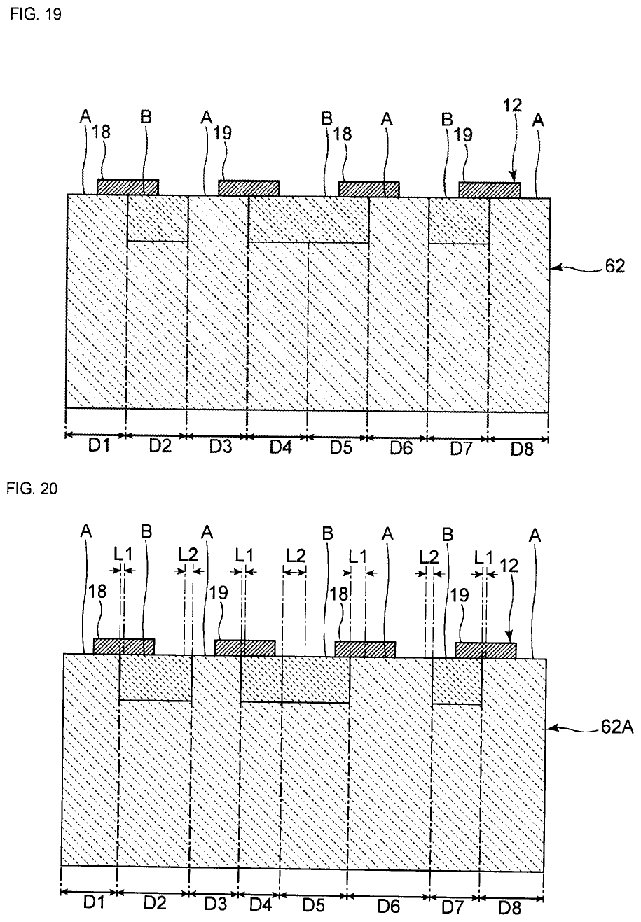

FIG. 19 is a schematic elevational cross-sectional view illustrating a vicinity of two pairs of electrode fingers of an acoustic wave device according to the sixth example embodiment.

The present example embodiment is different from the first example embodiment in a fact that a piezoelectric substrate 62 includes only a piezoelectric layer. The piezoelectric substrate 62 is a substrate made of only a piezoelectric material. The acoustic wave device of the present example embodiment has the same configuration as the acoustic wave device 1 of the first example embodiment in other respects than the above.

On the main surface on which the IDT electrode 12 is provided, in the piezoelectric substrate 62, the disposition of the first region A and the second region B is the same as that in the first example embodiment. However, the second region B is positioned at a portion of the piezoelectric substrate 62 in the thickness direction. The first region A and the second region B are laminated at the portion where the second region B is positioned in plan view.

As illustrated in FIG. 19, at the portion where the second region B is positioned in the thickness direction of the piezoelectric substrate 62, the boundary between the first region A and the second region B extends in the normal direction of the main surface of the piezoelectric substrate 62. In the piezoelectric substrate 62, the boundary between any one of the sections is also positioned at one of the center of the portion where the electrode fingers are provided in the electrode finger orthogonal direction and the center of the inter-electrode finger portion in the electrode finger orthogonal direction. Therefore, one of L1=0 and L2=0 is satisfied at the boundary between any sections.

In the polarization change region of the piezoelectric substrate 62, the relationship between the first to eighth sections D1 to D8 and the disposition of the first region A and the second region B is the same as that in the first example embodiment. Accordingly, the 1/2 harmonic wave can be excited and the fundamental wave can be suppressed. Therefore, the 1/2 harmonic wave can be preferably used for the operation of the acoustic wave device, and the fundamental wave as an unnecessary wave can be suppressed.

Hereinafter, the first to fourth modification examples of the sixth example embodiment, which are different from the sixth example embodiment only in the order of the disposition of the boundaries of each section, the disposition of the boundaries of the first region A and the second region B, or the disposition of the first region A and the second region B, will be described. In the first to fourth modification examples, similarly to the sixth example embodiment, the 1/2 harmonic wave can be excited and the fundamental wave can be suppressed.

In a piezoelectric substrate 62A of the first modification example illustrated in FIG. 20, one of L1>0 and L2>0 is satisfied at the boundaries between all of the sections.

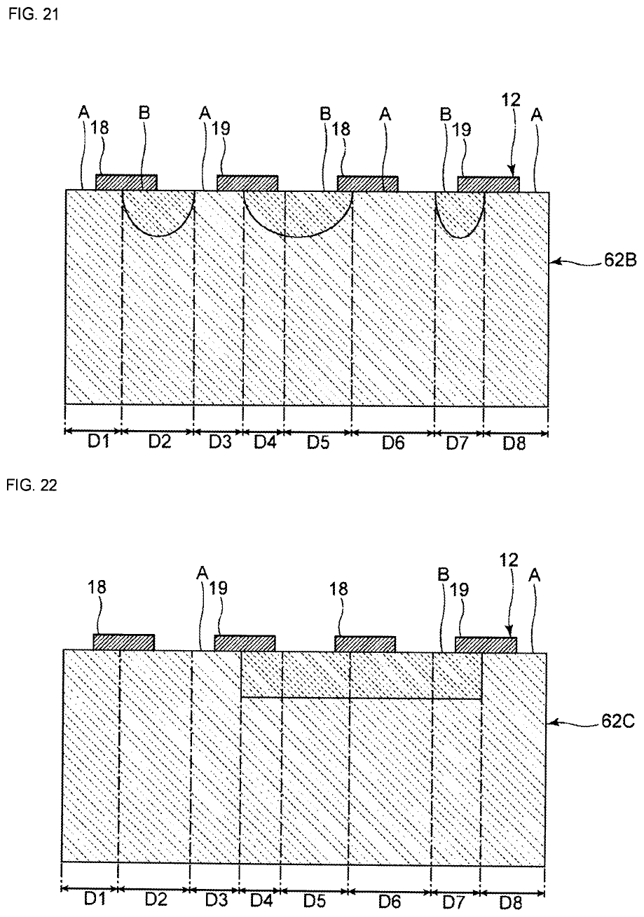

In a piezoelectric substrate 62B of the second modification example illustrated in FIG. 21, the boundary between the first region A and the second region B has a curved shape in the cross section along the electrode finger orthogonal direction. Specifically, the dimension of the second region B along the electrode finger orthogonal direction becomes smaller as the distance from the main surface on which the IDT electrode 12 is provided increases in the thickness direction of the piezoelectric substrate 62B. In addition, similarly to the first modification example, one of L1>0 and L2>0 is satisfied at the boundaries between all of the sections.

In a piezoelectric substrate 62C of the third modification example illustrated in FIG. 22, similarly to the second example embodiment, the disposition of the first region A and the second region B in the polarization change regions is 1/1/1/2/2/2/2/1. In addition, similarly to the first modification example, one of L1>0 and L2>0 is satisfied at the boundaries between all of the sections.

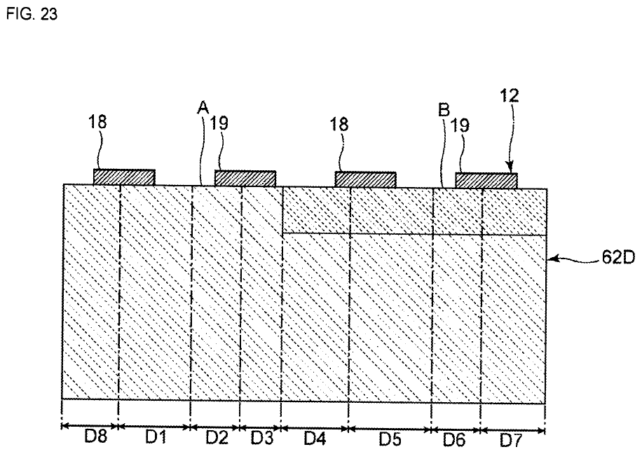

In a piezoelectric substrate 62D of the fourth modification example illustrated in FIG. 23, the boundary between the first section D1 and the second section D2 is positioned in the inter-electrode finger portion. The disposition of the first region A and the second region B in the polarization change regions may be 1/1/1/1/2/2/2/2. In addition, similarly to the first modification example, one of L1>0 and L2>0 is satisfied at the boundaries between all of the sections.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
an IDT electrode provided on the piezoelectric layer, and including a plurality of first electrode fingers and a plurality of second electrode fingers that are interdigitated with each other and coupled to mutually different potentials; wherein
a portion of the piezoelectric layer where the IDT electrode is provided includes an intersection region, and when a direction in which the plurality of first electrode fingers and the plurality of second electrode fingers extend is defined as an electrode finger extending direction, a direction orthogonal to the electrode finger extending direction is defined as an electrode finger orthogonal direction, and the IDT electrode is viewed in the electrode finger orthogonal direction, a region where the first electrode finger and the second electrode finger, which are adjacent to each other, overlap each other is the intersection region;
the piezoelectric layer includes a first region and a second region having a polarization direction different from that of the first region, and the first region and the second region are positioned at least in the intersection region;
the intersection region includes a polarization change region where the first region and the second region are alternately arranged in the electrode finger orthogonal direction;
in plan view, each first region and each second region positioned in the polarization change region overlap at least a portion of at least one of the first electrode finger and the second electrode finger;
when the piezoelectric layer is divided into a plurality of sections in the electrode finger orthogonal direction, each of the plurality of sections is defined as an area extending from a portion where the first electrode finger or the second electrode finger is provided to a portion where the first electrode finger or the second electrode finger is not provided, and only one electrode finger is provided in each of the sections among the plurality of first electrode fingers and the plurality of second electrode fingers, the plurality of sections include first to eighth sections arranged in order in the electrode finger orthogonal direction;
a boundary between the first section and the second section is positioned at a portion where the first electrode finger is provided; and
the first region is positioned in the first section, the second region is positioned in the second section, the first region is positioned in the third section, the second region is positioned in the fourth section, the second region is positioned in the fifth section, the first region is positioned in the sixth section, the second region is positioned in the seventh section, and the first region is positioned in the eighth section.

2. The acoustic wave device according to claim 1, wherein an angle defined by a polarization axis in the first region and a polarization axis in the second region is within a range of about 180°±5°.

3. The acoustic wave device according to claim 1, wherein at least one boundary among boundaries between the first region and the second region positioned in the first to eighth sections is positioned at a portion where any electrode finger is provided among the plurality of first electrode fingers and the plurality of second electrode fingers, and when a distance in the electrode finger orthogonal direction between the boundary and a center of the electrode finger in the electrode finger orthogonal direction is defined as L1, and an electrode finger pitch of the portion where the electrode finger is positioned is defined as p1, L1/p1<about 0.1.

4. The acoustic wave device according to claim 1, wherein
when a portion between the first electrode finger and the second electrode finger, which are adjacent to each other, is defined as an inter-electrode finger portion, at least one boundary among boundaries between the first region and the second region positioned in the first to eighth sections is positioned in any one inter-electrode finger portion among the plurality of inter-electrode finger portions, and when a distance in the electrode finger orthogonal direction between the boundary and a center of the inter-electrode finger portion in the electrode finger orthogonal direction is defined as L2, and an electrode finger pitch of the portion where the inter-electrode finger portion is positioned is defined as p2, L2/p2<about 0.1.

5. The acoustic wave device according to claim 1, wherein in the first to eighth sections, when a total of dimensions along the electrode finger orthogonal direction of the first region is defined as E1, and a total of dimensions along the electrode finger orthogonal direction of the second region is defined as E2, E2/E1 is within a range of about 1±0.1.

6. The acoustic wave device according to claim 1, wherein
the piezoelectric substrate includes a high acoustic velocity layer;
the piezoelectric layer is provided directly or indirectly on the high acoustic velocity layer; and
an acoustic velocity of a bulk wave that propagates through the high acoustic velocity layer is higher than an acoustic velocity of an acoustic wave that propagates through the piezoelectric layer.

7. The acoustic wave device according to claim 1, wherein
the piezoelectric substrate includes an acoustic reflection film;
the piezoelectric layer is provided directly or indirectly on the acoustic reflection film; and
the acoustic reflection film includes at least one low acoustic impedance layer having a relatively low acoustic impedance and at least one high acoustic impedance layer having a relatively high acoustic impedance, and the low acoustic impedance layer and the high acoustic impedance layer are alternately laminated.

8. The acoustic wave device according to claim 1, wherein
the piezoelectric substrate includes an electrode layer; and
the piezoelectric layer is provided directly or indirectly on the electrode layer.

9. The acoustic wave device according to claim 1, wherein
the piezoelectric substrate includes a silicon oxide film; and
the piezoelectric layer is provided directly or indirectly on the silicon oxide film.

10. An acoustic wave device comprising:
a piezoelectric substrate including a piezoelectric layer; and
an IDT electrode provided on the piezoelectric layer, and including a plurality of first electrode fingers and a plurality of second electrode fingers that are interdigitated with each other and coupled to mutually different potentials; wherein
a portion of the piezoelectric layer where the IDT electrode is provided includes an intersection region, and when a direction in which the plurality of first electrode fingers and the plurality of second electrode fingers extend is defined as an electrode finger extending direction, a direction orthogonal to the electrode finger extending direction is defined as an electrode finger orthogonal direction, and the IDT electrode is viewed in the electrode finger orthogonal direction, a region where the first electrode finger and the second electrode finger, which are adjacent to each other, overlap each other is the intersection region;
the piezoelectric layer includes a first region and a second region having a polarization direction different from that of the first region, and the first region and the second region are positioned at least in the intersection region;
the intersection region includes a polarization change region where the first region and the second region are alternately arranged in the electrode finger orthogonal direction;
in plan view, each first region and each second region positioned in the polarization change region overlap at least a portion of at least one of the first electrode finger and the second electrode finger;
when the piezoelectric layer is divided into a plurality of sections in the electrode finger orthogonal direction, each of the plurality of sections is defined as an area extending from a portion where the first electrode finger or the second electrode finger is provided to a portion where the first electrode finger or the second electrode finger is not provided, and only one electrode finger is provided in each of the sections among the plurality of first electrode fingers and the plurality of second electrode fingers, the plurality of sections include first to eighth sections arranged in order in the electrode finger orthogonal direction; and
the first region is positioned in the first section, the first region is positioned in the second section, the first region is positioned in the third section, the second region is positioned in the fourth section, the second region is positioned in the fifth section, the second region is positioned in the sixth section, the second region is positioned in the seventh section, and the first region is positioned in the eighth section.

11. The acoustic wave device according to claim 10, wherein a boundary between the first section and the second section is positioned at a portion where the first electrode finger is provided.

12. The acoustic wave device according to claim 10, wherein an angle defined by a polarization axis in the first region and a polarization axis in the second region is within a range of about 180°±5°.

13. The acoustic wave device according to claim 10, wherein at least one boundary among boundaries between the first region and the second region positioned in the first to eighth sections is positioned at a portion where any electrode finger is provided among the plurality of first electrode fingers and the plurality of second electrode fingers, and when a distance in the electrode finger orthogonal direction between the boundary and a center of the electrode finger in the electrode finger orthogonal direction is defined as L1, and an electrode finger pitch of the portion where the electrode finger is positioned is defined as p1, L1/p1<about 0.1.

14. The acoustic wave device according to claim 10, wherein
when a portion between the first electrode finger and the second electrode finger, which are adjacent to each other, is defined as an inter-electrode finger portion, at least one boundary among boundaries between the first region and the second region positioned in the first to eighth sections is positioned in any one inter-electrode finger portion among the plurality of inter-electrode finger portions, and when a distance in the electrode finger orthogonal direction between the boundary and a center of the inter-electrode finger portion in the electrode finger orthogonal direction is defined as L2, and an electrode finger pitch of the portion where the inter-electrode finger portion is positioned is defined as p2, L2/p2<about 0.1.

15. The acoustic wave device according to claim 10, wherein in the first to eighth sections, when a total of dimensions along the electrode finger orthogonal direction of the first region is defined as E1, and a total of dimensions along the electrode finger orthogonal direction of the second region is defined as E2, E2/E1 is within a range of about 1±0.1.

16. The acoustic wave device according to claim 10, wherein
the piezoelectric substrate includes a high acoustic velocity layer;
the piezoelectric layer is provided directly or indirectly on the high acoustic velocity layer; and
an acoustic velocity of a bulk wave that propagates through the high acoustic velocity layer is higher than an acoustic velocity of an acoustic wave that propagates through the piezoelectric layer.

17. The acoustic wave device according to claim 10, wherein
the piezoelectric substrate includes an acoustic reflection film;
the piezoelectric layer is provided directly or indirectly on the acoustic reflection film; and
the acoustic reflection film includes at least one low acoustic impedance layer having a relatively low acoustic impedance and at least one high acoustic impedance layer having a relatively high acoustic impedance, and the low acoustic impedance layer and the high acoustic impedance layer are alternately laminated.

18. The acoustic wave device according to claim 10, wherein
the piezoelectric substrate includes an electrode layer; and
the piezoelectric layer is provided directly or indirectly on the electrode layer.

19. The acoustic wave device according to claim 10, wherein
the piezoelectric substrate includes a silicon oxide film; and
the piezoelectric layer is provided directly or indirectly on the silicon oxide film.
